(19) United States
(12) Patent Application Publication
(10) Pub. No.: US 2026/0060055 A1
(43) Pub. Date: Feb. 26, 2026

(54) METHOD FOR TREATING SEMICONDUCTOR SUBSTRATE

(71) Applicant: TOKUYAMA CORPORATION, Yamaguchi (JP)

(72) Inventors: Yuki KIKKAWA, Yamaguchi (JP); Yuzan SUZUKI, Yamaguchi (JP)

(73) Assignee: TOKUYAMA CORPORATION, Yamaguchi (JP)

(21) Appl. No.: 19/298,540

(22) Filed: Aug. 13, 2025

(30) Foreign Application Priority Data
Aug. 20, 2024 (JP) 2024-138966

(51) Int. Cl. H01L 21/768

(52) U.S. Cl. CPC H01L 21/76879; H01L 21/7684; H01L 21/7688

(57) ABSTRACT

A method for treating a semiconductor substrate containing a refractory metal and copper, the method including: an oxidation treatment step of forming copper oxide on a surface of the copper; and a step of removing the refractory metal after the oxidation treatment step.

### TECHNICAL FIELD

The present invention relates to a method for treating a semiconductor substrate.

### BACKGROUND ART

In semiconductor elements, a wiring layer is formed for the purpose of extracting an electric signal that a transistor outputs to the outside. The miniaturization of semiconductor elements has been progressing year by year, and when a material with low electromigration resistance or high resistance is used, decreased reliability of semiconductor elements or an inhibition of high-speed operation will be caused. Accordingly, as a wiring material, there has been a demand for a material having high electromigration resistance and a low resistance value.

As a material having high electromigration resistance and a low resistance value, for example, aluminum or copper has been used so far. A metal wiring is formed on a pattern exposed on an insulating film, but when a wiring width becomes shorter, an embedding property of the metal becomes worse, and there is a problem that a short circuit is caused by formation of a void. Thus, to improve the embedding property of the metal, a method in which a thin metal film, called a liner layer, is formed on a dielectric and a wiring metal is formed thereon is used. As a metal to be used for the liner layer for copper wiring, a refractory metal such as cobalt or ruthenium has been studied.

When a wiring layer is formed in a semiconductor element, a step of processing a wiring material is included, and dry or wet etching is used in this step. In wet-etching a metal of the liner layer, if the wiring metal is also etched at the same time, there is a risk of an increase in resistance or a short circuit due to surface roughness, and thus it is required to selectively etch only the metal of the liner layer.

As a treatment liquid capable of etching a specific metal, Patent Document 1 discloses an etching liquid for etching ruthenium, the etching liquid containing orthoperiodic acid and ammonia and having a pH of 8 or more and 10 or less.

Patent Document 2 discloses a treatment liquid for washing a semiconductor wafer, the treatment liquid containing a hypochlorite ion and a solvent, and having a pH of higher than 7 and lower than 12.0 at 25° C.

### PRIOR ART DOCUMENTS

### Patent Document

Patent Document 1: JP 2021-090040 A
Patent Document 2: WO 2019/142788

### SUMMARY OF INVENTION

### Technical Problem

However, according to the study of the present inventors, it has been found that, in the case where copper is used as a wiring metal, the etching liquid of Patent Document 1 cannot selectively etch only the metal of the liner layer because copper is etched simultaneously with the metal of the liner layer.

It has been also found that the etching liquid of Patent Document 2 can etch a refractory metal such as ruthenium, but slightly dissolves copper. In addition, along with the dissolution of copper, a precipitate may be formed on the surface of copper.

The reason why the etching liquid described in Patent Document 1 cannot selectively etch only the refractory metal is not clear, but it is presumed that when the etching liquid comes into contact with copper, a corrosion potential of copper is higher than that of the refractory metal, and thus galvanic corrosion occurs.

The present invention provides a method for treating a semiconductor substrate, which is capable of selectively removing a refractory metal from the semiconductor substrate containing the refractory metal and copper.

### Solution to Problem

As a result of intensive studies to solve the above problems, the present inventors have found that a refractory metal can be selectively removed by a method for treating a semiconductor substrate, the method including an oxidation treatment step of forming copper oxide on a surface of copper and a step of removing the refractory metal after the oxidation treatment step.

That is, the gist of the present invention is specifically as follows.
[1]: A method for treating a semiconductor substrate containing a refractory metal and copper, the method including:
an oxidation treatment step of forming copper oxide on a surface of the copper; and
a step of removing the refractory metal after the oxidation treatment step.
[2]: The method according to [1], wherein the oxidation treatment step is a step of bringing a solution containing an oxidizer into contact with the semiconductor substrate.
[3]: The method according to [1] or [2], wherein the oxidizer is one or more types selected from the group consisting of a hexacyanide metal complex and a halogen oxyacid ion.
[4]: The method according to any of [1] to [3], wherein the step of removing the refractory metal is a step of bringing a treatment liquid containing a hypohalite ion into contact with the semiconductor substrate.
[5]: The method according to any of [1] to [4], wherein the refractory metal is one or more metals selected from the group consisting of titanium, tantalum, ruthenium, molybdenum, tungsten, chromium, iridium, rhodium, platinum, and niobium.
[6]: A method for manufacturing a semiconductor substrate, the method including the method according to any of [1] to [5].

### Effects of Invention

According to the present invention, it is possible to provide a method for treating a semiconductor substrate, which can selectively remove a refractory metal from a semiconductor substrate containing the refractory metal and copper.

### BRIEF DESCRIPTION OF DRAWINGS

FIG. 1 is a schematic view of a wiring formation step of a semiconductor substrate.

FIG. 2 is a schematic view of an instrument used for preparing an aqueous sodium hypobromite solution used in Examples.

FIG. 3 is a schematic view of an instrument used for preparing an aqueous tetramethylammonium hypochlorite solution used in Examples.

### DESCRIPTION OF EMBODIMENTS

Embodiments of the present invention are described in detail below, but as long as the gist of the present invention is observed, the present invention is not limited to the details described below. In addition, the present invention can be modified and implemented in any manner that does not depart from the gist of the present invention. Further, when numerical ranges are described in a stepwise manner, the upper limit and the lower limit of each numerical range can be optionally combined.

In addition, the expression “A or B” in the present specification can be read as “at least one selected from the group consisting of A and B”.

In addition, the expression “an amount of B relative to an amount of A” in the present specification represents “amount of B/amount of A”.

In addition, although a plurality of embodiments will be described in the present specification, various conditions in the embodiments can be applied to each other within an applicable range.

### (Method for Treating Semiconductor Substrate)

A method for treating a semiconductor substrate according to an embodiment of the present invention is a method for treating a semiconductor substrate containing a refractory metal and copper, the method including an oxidation treatment step of forming copper oxide on a surface of the copper, and a step of removing the refractory metal after the oxidation treatment step.

### (Semiconductor Substrate)

When the semiconductor substrate is treated by the above method, the refractory metal contained in the semiconductor substrate can be selectively removed (etched) with respect to copper.

The refractory metal contained in the semiconductor substrate is present as a film formed on the semiconductor substrate as a liner layer, for example.

Copper is present on a semiconductor substrate or a liner layer as a wiring, for example.

The semiconductor substrate is not limited as long as it contains a refractory metal and copper, and the treatment method according to an embodiment of the present invention can be applied to a known substrate used for a semiconductor. Examples of the semiconductor substrate include a variety of substrates such as a semiconductor wafer, a glass substrate, and an organic resin substrate.

### (Refractory Metal)

In the present specification, the refractory metal is a metal having a melting point of 1400° C. or higher. Specific examples thereof include one or more types selected from the group consisting of titanium, tantalum, ruthenium, molybdenum, tungsten, chromium, iridium, rhodium, platinum, and niobium. The refractory metal preferably includes ruthenium, molybdenum, or tungsten, and most preferably includes ruthenium.

The metal can include an alloy. The metal can also include a metal compound such as an oxide, a nitride, or an oxynitride of each of the above metals.

### (Oxidation Treatment Step)

The oxidation treatment step is intended to form a copper oxide film on the surface of copper. The copper oxide film formed by the oxidation treatment step is a dense film having resistance to many oxidizers. Thus, dissolution of copper by a treatment liquid to be used in a subsequent step of removing the refractory metal is suppressed, and only the refractory metal can be selectively removed.

The method of the oxidation treatment step is not particularly limited, but preferably includes a step of bringing an oxidizing gas such as oxygen or carbon dioxide into contact with the semiconductor substrate, or a step of bringing a solution containing an oxidizer (hereinafter referred to as an oxidation treatment liquid) into contact with the semiconductor substrate.

The oxidizer to be contained in the oxidation treatment liquid is not particularly limited as long as it can form an oxide film on the copper surface without dissolving copper and does not affect the refractory metal. Specific examples of the oxidizer include at least one selected from the group consisting of a hexacyanide metal complex, a halogen oxyacid ion, and a peroxodisulfate. The oxidizer is preferably at least one or more types selected from the group consisting of a hexacyanide metal complex and a halogen oxyacid ion.

The hexacyanide metal complex is, for example, a hexacyanidoferrate (III) complex, and specific examples thereof include sodium hexacyanidoferrate (III), potassium hexacyanidoferrate (III), and quaternary ammonium hexacyanidoferrate (III). Specific examples of the quaternary ammonium include one or more types selected from the group consisting of tetramethylammonium, ethyltrimethylammonium, tetraethylammonium, propyltrimethylammonium, tetrapropylammonium, butyltrimethylammonium, and tetrabutylammonium.

In a case where the oxidation treatment liquid contains a hexacyanide metal complex, the concentration of the hexacyanide metal complex is not particularly limited as long as the oxidation treatment liquid does not depart from the object of the present invention, but is preferably 0.0001 mol/L or more and 0.1 mol/L or less. When the concentration of the hexacyanide metal complex is 0.1 mol/L or less, an oxide film is hardly formed on the surface of the refractory metal, and thus, etching of the refractory metal in the subsequent step of removing the refractory metal is hardly inhibited. When the concentration of the hexacyanide metal complex is 0.0001 mol/L or more, a rate of forming copper oxide on the copper surface is sufficient. The hexacyanide metal complex is preferably 0.001 mol/L or more and 0.1 mol/L or less, and more preferably 0.005 mol/L or more and 0.1 mol/L or less, with respect to the total volume of the oxidation treatment liquid, from the viewpoint of influence on the refractory metal and the rate of forming the oxide film on the surface of copper.

Examples of the halogen oxyacid ion include one or more types selected from the group consisting of a chlorate ion, a bromate ion, an iodate ion, a chlorite ion, and a bromite ion. Specific examples of the source of the halogen oxyacid ion include one or more types selected from the group consisting of sodium chlorate, sodium bromate, sodium iodate, sodium chlorite, sodium bromite, quaternary ammonium chlorate, quaternary ammonium bromate, quaternary ammonium iodate, quaternary ammonium chlorite, and quaternary ammonium bromite. Specific examples of the quaternary ammonium include one or more types selected from the group consisting of tetramethylammonium, ethyltrimethylammonium, tetraethylammonium, propyltrimethylammonium, tetrapropylammonium, butyltrimethylammonium, and tetrabutylammonium.

In a case where the oxidation treatment liquid contains the halogen oxyacid ion, the concentration of the halogen oxyacid ion is not limited as long as the oxidation treatment liquid does not depart from the present object, but is preferably 0.0001 mol/L or more and 5.0 mol/L or less. When the concentration of the halogen oxyacid ion is 5.0 mol/L or less, deposition of halogen oxoate on the copper surface can be suppressed. When the concentration of the halogen oxyacid ion is 0.0001 mol/L or more, the rate of forming copper oxide on the copper surface is sufficient. The concentration of the halogen oxyacid ion is preferably 0.001 mol/L or more and 0.5 mol/L or less, and more preferably 0.005 mol/L or more and 0.1 mol/L or less, with respect to the total volume of the oxidation treatment liquid, from the viewpoint of preventing deposition of the halogen oxoate onto the copper surface and the rate of forming an oxide film on the copper surface.

Examples of the peroxodisulfate include one or more types selected from the group consisting of sodium peroxodisulfate, ammonium peroxodisulfate, and quaternary ammonium peroxodisulfate. Specific examples of the quaternary ammonium include one or more types selected from the group consisting of tetramethylammonium, ethyltrimethylammonium, tetraethylammonium, propyltrimethylammonium, tetrapropylammonium, butyltrimethylammonium, and tetrabutylammonium.

In a case where the oxidation treatment liquid contains a peroxodisulfate, the concentration thereof is preferably 0.001 mol/L or more and 0.5 mol/L or less, and more preferably 0.005 mol/L or more and 0.1 mol/L or less, with respect to the total volume of the oxidation treatment liquid, from the viewpoint of preventing deposition of the peroxodisulfate on the copper surface and the rate of forming an oxide film on the copper surface.

### (Solvent)

Examples of the solvent of the oxidation treatment liquid include water and an organic solvent, and water is most preferably used. Water contained in the oxidation treatment liquid is preferably water from which metal ions, organic impurities, particles, or the like have been removed by a treatment such as distillation, ion exchange, filtration, or various types of adsorption, and pure water or ultrapure water is particularly preferable.

The organic solvent is preferably a water-soluble organic solvent that can be mixed with water at an arbitrary proportion. Examples of the water-soluble organic solvent include one or more types selected from the group consisting of an ether-based solvent, an alcohol-based solvent, a ketone-based solvent, an amide-based solvent, a nitrile solvent, a sulfur-containing solvent, and a lactone-based solvent.

Examples of the ether-based solvent include one or more types selected from the group consisting of diethyl ether, isopropyl ether, tert-butyl methyl ether, tetrahydrofuran, diethylene glycol dimethyl ether, triethylene glycol dimethyl ether, diethylene glycol butyl methyl ether, diethylene glycol diethyl ether, tetraethylene glycol dimethyl ether, diethylene glycol ethyl methyl ether, ethylene glycol dibutyl ether, and 1,2-diethoxyethane.

Examples of the alcohol-based solvent include one or more types selected from the group consisting of methanol, ethanol, 1-propanol, 2-propanol, 1-butanol, 2-butanol, 2-methoxyethanol, ethylene glycol monobutyl ether, and 2-ethoxyethanol.

Examples of the ketone-based solvent include one or more types selected from the group consisting of acetone, 2-butanone, 3-pentanone, cyclohexanone, and cyclopentanone.

Examples of the amide-based solvent include one or more types selected from the group consisting of formamide, monomethylformamide, dimethylformamide, acetamide, monomethylacetamide, dimethylacetamide, monoethylacetamide, and diethylacetamide.

Examples of the nitrile solvent include one or more types selected from the group consisting of acetonitrile, propionitrile, glutaronitrile, and 3,3′-oxydipropionitrile.

Examples of the sulfur-containing solvent include dimethyl sulfone and sulfolane.

Examples of the lactone-based solvent include γ-butyrolactone and ε-caprolactone.

The amount of the solvent is not particularly limited, and can be appropriately adjusted in such a manner that the concentration of the oxidizer in the oxidation treatment liquid becomes a desired concentration.

### (Step of Removing Refractory Metal)

The step of removing a refractory metal (hereinafter referred to as the removal step) according to an embodiment of the present invention is a step following the oxidation treatment step. The order of the removal step is not particularly limited as long as it is after the oxidation treatment step. For example, the removal step can be performed immediately after the oxidation treatment step, or a step of washing the oxidizer used in the oxidation treatment step or another step can be optionally performed between the oxidation treatment step and the removal step.

The removal step is not particularly limited as long as it is a method capable of removing the refractory metal, and can include a physical treatment or a chemical treatment, but preferably includes a step of bringing a treatment liquid containing a hypohalite ion into contact with the semiconductor substrate.

Preferably, the removal step is a step of selectively removing the refractory metal with respect to copper. Here, the phrase “selectively removing, with respect to copper” means that the value of a ratio of etching rates (etching rate of refractory metal/etching rate of copper) described below in Examples is 50 or more.

### (Hypohalite Ion)

The treatment liquid to be used in the removal step (hereinafter referred to as the treatment liquid for removal) is preferably capable of selectively removing only the refractory metal without removing the oxide film formed by the oxidation treatment step. Specific examples of such a treatment liquid for removal include a treatment liquid containing a hypohalite ion. The treatment liquid for removal preferably contains one or more types of hypohalite ions selected from the group consisting of a hypochlorite ion and a hypobromite ion. The concentration thereof is not particularly limited as long as the treatment liquid for removal does not depart from the object of the present invention, but is preferably 0.0001 mol/L or more and 1.0 mol/L or less.

When the concentration of the hypohalite ion is 1.0 mol/L or less, decomposition of the hypohalite ion is suppressed, and the function as an oxidizer is sufficiently exhibited. When the concentration of the hypohalite ion is 0.0001 mol/L or more, the etching rate of the refractory metal becomes sufficient. The concentration of the hypohalite ion contained in the treatment liquid for removal of the present embodiment is preferably 0.001 mol/L or more and 0.5 mol/L or less, and more preferably 0.005 mol/L or more and 0.1 mol/L or less, with respect to the total volume of the treatment liquid for removal, from the viewpoint of the stability of the treatment liquid for removal and the dissolution rate of the refractory metal.

The treatment liquid for removal can contain only one type of hypohalite ion or can contain two or more types of hypohalite ions. The concentration range of the hypohalite ion indicates the concentration range of one type of hypochlorite ion or hypobromite ion in a case where the hypochlorite ion or the hypobromite ion is contained alone, and indicates the total concentration range of two or more types in a case where the two or more types of hypohalite ions are contained.

Examples of a method for incorporating one or more types of hypohalite ions selected from the group consisting of a hypobromite ion and a hypochlorite ion into the treatment liquid for removal include a method of adding a hypohalite, a method of adding chlorine or bromine to an alkaline solution, and a method of generating a hypobromite ion by adding a bromine-containing compound and an oxidizer in a case of the hypobromite ion.

Examples of the hypohalite include one or more selected from the group consisting of sodium hypochlorite, potassium hypochlorite, sodium hypobromite, and potassium hypobromite.

Examples of the alkaline solution include one or more types selected from the group consisting of an aqueous sodium hydroxide solution, an aqueous potassium hydroxide solution, and an aqueous tetramethylammonium solution.

### (Alkali Metal or Alkaline Earth Metal)

The treatment liquid for removal can contain an alkali metal or an alkaline earth metal within a range not impairing the object of the present invention. Specific examples of the alkali metal include one or more types selected from the group consisting of Na, K, and Rb. Specific examples of the alkaline earth metal include one or more types selected from the group consisting of Mg, Ca, and Sr. The alkali metal or the alkaline earth metal functions as an oxidation accelerator of the refractory metal. It is presumed that the metal is present in the treatment liquid in the form of a metal ion. The concentration thereof is not particularly limited as long as the treatment liquid for removal does not depart from the object of the present invention, but is preferably 0.0001 mass % or more and 10.0 mass % or less, with respect to the total mass of the treatment liquid for removal. When the concentration of the alkali metal or the alkaline earth metal is 10.0 mass % or less, decomposition of the hypohalite ion is suppressed, and thus, it is preferable in terms of the stability of the hypohalite ion. When the concentration is 0.0001 mass % or more, an oxidation promotion effect of the refractory metal is sufficiently obtained. The alkali metal or alkaline earth metal contained in the treatment liquid for removal is preferably 0.001 mass % or more and 5.0 mass % or less, and more preferably 0.01 mass % or more and 1.0 mass % or less, with respect to the total mass of the treatment liquid for removal, from the viewpoint of the stability of the treatment liquid for removal and the oxidation promotion effect of the refractory metal.

Two or more types of these alkali metals or alkaline earth metals can be contained in the treatment liquid for removal. In this case, the total concentration of the alkali metal and the alkaline earth metal is preferably 0.005 mass % or more and 5.0 mass % or less, and more preferably 0.01 mass % or more and 1.0 mass % or less.

Examples of a method for incorporating the alkali metal or the alkaline earth metal into the treatment liquid for removal include a method of adding a salt of the alkali metal or the alkaline earth metal, specifically, a fluoride, a chloride, a bromide, an iodide, a hydroxide, or the like of the alkali metal or the alkaline earth metal to the treatment liquid for removal as described below.

### (Chloride Ion or Bromide Ion)

The treatment liquid for removal can contain a chloride ion or a bromide ion within a range not impairing the object of the present invention. When the treatment liquid for removal contains a hypochlorite ion, it is preferable to contain a chloride ion, and when the treatment liquid for removal contains a hypobromite ion, it is preferable to contain a bromide ion.

The chloride ion can be contained in the treatment liquid for removal by adding, for example, chlorine gas, hydrogen chloride, or a chloride. The content of the chloride ion can be adjusted by the mass of chlorine gas, hydrogen chloride, or a chloride added to the treatment liquid.

The bromide ion can be contained in the treatment liquid for removal by adding, for example, bromine gas, hydrogen bromide, or a bromide. The content of the bromide ion can be adjusted by the mass of bromine gas, hydrogen bromide, or a bromide added to the treatment liquid.

The concentration of the chloride ion or bromide ion is not limited as long as the treatment liquid for removal does not depart from the object of the present invention, but is preferably 0.0001 mol/L or more and 5.0 mol/L or less. When the concentration of the chloride ion or bromide ion is 5.0 mol/L or less, corrosion of copper can be suppressed. When the concentration of the chloride ion or bromide ion is 0.0001 mol/L or more, the removing rate (etching rate) of the refractory metal becomes sufficient. The concentration of the chloride ion or bromide ion contained in the treatment liquid for removal is preferably 0.001 mol/L or more and 3.0 mol/L or less, and more preferably 0.005 mol/L or more and 1.0 mol/L or less, with respect to the total volume of the treatment liquid, from the viewpoint of suppressing copper corrosion and the etching rate of the refractory metal.

In addition, two types of the chloride ion or bromide ion can be contained in the treatment liquid. In this case, the total concentration of the chloride ion and bromide ion is preferably 0.0001 mol/L or more and 5.0 mol/L or less and more preferably 0.001 mol/L or more and 3.0 mol/L or less.

### (Halogen Oxyacid Ion)

The treatment liquid for removal can contain a halogen oxyacid ion as long as the object of the present invention is not impaired. Specifically, the halogen oxyacid ion is preferably one or more types selected from the group consisting of a chlorate ion, a chlorite ion, a bromate ion, and a bromite ion.

The chlorate ion can be contained in the treatment liquid for removal by adding, for example, chloric acid or a chlorate. The content of the chlorate ion can be adjusted by the mass of chloric acid or a chlorate added to the treatment liquid for removal.

The chlorite ion can be contained in the treatment liquid for removal by adding, for example, chlorous acid or a chlorite. The content of the chlorite ion can be adjusted by the mass of chlorous acid or a chlorite added to the treatment liquid for removal.

The bromate ion can be contained in the treatment liquid for removal by adding, for example, bromic acid or a bromate. The content of the bromate ion can be adjusted by the mass of bromic acid or a bromate added to the treatment liquid for removal.

The bromite ion can be contained in the treatment liquid for removal by adding, for example, bromous acid or a bromite. The content of the bromite ion can be adjusted by the mass of bromous acid or a bromite added to the treatment liquid for removal.

The concentration of the halogen oxyacid ion in the treatment liquid for removal is not particularly limited as long as the treatment liquid for removal does not depart from the object of the present invention, but the concentration is preferably 0.1 mmol/L or more and 1.0 mol/L or less. When the concentration of the halogen oxyacid ion is 1.0 mol/L or less, deposition of the halogen oxoate on the copper surface can be suppressed. When the concentration of the halogen oxyacid ion is 0.1 mmol/L or more, corrosion of copper can be suppressed. The concentration of the halogen oxyacid ion is preferably 1.0 mmol/L or more and 0.5 mol/L or less, and more preferably 10.0 mmol/L or more and 0.1 mol/L or less, with respect to the total volume of the treatment liquid for removal, from the viewpoint of preventing deposition of the halogen oxoate onto the copper surface and suppressing corrosion of copper. Two or more types of these halogen oxyacid ions can be contained in the treatment liquid for removal. In this case, the total concentration of the halogen oxyacid ions is preferably 1.0 mmol/L or more and 0.5 mol/L or less and more preferably 10 mmol/L or more and 0.1 mol/L or less.

In addition, in a case where the hypochlorite ion or the chloride ion is contained in the treatment liquid for removal, it is preferable to contain the chlorate ion as the halogen oxyacid ion, and in a case where the hypobromite ion or the bromide ion is contained in the treatment liquid, it is preferable to contain the bromate ion as the halogen oxyacid ion.

(pH)

The pH of the treatment liquid for removal is preferably pH 7.0 to 14.0. When the pH is 7.0 or more, storage stability of the hypohalite ion becomes good. When the pH is 14.0 or less, the etching rate for the refractory metal becomes sufficient. The storage stability is evaluated as a change in concentration of the hypohalite ion when the treatment liquid for removal is stored for a long period of time.

The pH of the treatment liquid for removal is more preferably pH 9.0 to 13.0, and even more preferably pH 11.0 to 13.0, from the viewpoint of the ability to dissolve the refractory metal and the storage stability of the treatment liquid. Note that, the pH herein is a value at 25° C.

To adjust the pH of the treatment liquid for removal, an acid or a base can be used. Examples of the base include an inorganic base (inorganic alkali) and an organic base (organic alkali). The inorganic base is composed of a metal ion and a hydroxide ion, and specific examples thereof include one or more types selected from the group consisting of lithium hydroxide, sodium hydroxide, potassium hydroxide, magnesium hydroxide, calcium hydroxide, rubidium hydroxide, strontium hydroxide, and barium hydroxide. It is particularly preferable to use an inorganic base for the pH adjustment of the treatment liquid for removal.

The organic base is composed of an organic cation and a hydroxide ion. An example of the organic cation is an onium ion. An onium ion is a compound of a polyatomic cation formed by addition of excess protons (hydrogen cations) to a monatomic anion. Specific examples thereof include one or more types of cations selected from the group consisting of an imidazolium ion, a pyrrolidinium ion, a pyridinium ion, a piperidinium ion, an ammonium ion, a phosphonium ion, a fluoronium ion, a chloronium ion, a bromonium ion, an iodonium ion, an oxonium ion, a sulfonium ion, a selenonium ion, a telluronium ion, an arsonium ion, a stibonium ion, or a bismuthonium ion. Among these, one or more types selected from the group consisting of an ammonium ion, a phosphonium ion, and a sulfonium ion are suitable as the organic cation contained in the organic alkali of the present embodiment because they are stably present in an alkali solution, can easily modify a carbon chain or a functional group contained in the onium ion, and can easily control solubility, bulkiness, and charge density.

From the viewpoint of enabling mass production at low cost on an industrial scale, the onium ion is more suitably an ammonium ion. Examples of such an ammonium ion include a tetraalkylammonium ion, and more suitable examples thereof include one or more types selected from the group consisting of a tetramethylammonium ion, an ethyltrimethylammonium ion, a tetraethylammonium ion, a propyltrimethylammonium ion, a tetrapropylammonium ion, a butyltrimethylammonium ion, and a tetrabutylammonium ion. The organic alkali containing an onium ion and a hydroxide ion, that is, onium hydroxide can be suitably used as the organic alkali. In addition, an organic alkali containing an ammonium ion (NH₄⁺) or 2-hydroxyethyltrimethylammonium as an organic cation can also be suitably used as the organic alkali of the present embodiment.

The organic alkali is particularly preferably tetraalkylammonium hydroxide. Examples of the tetraalkylammonium hydroxide include one or more types selected from the group consisting of tetramethylammonium hydroxide, ethyltrimethylammonium hydroxide, tetraethylammonium hydroxide, propyltrimethylammonium hydroxide, tetrapropylammonium hydroxide, butyltrimethylammonium hydroxide, and tetrabutylammonium hydroxide.

Examples of the acid include an inorganic acid and an organic acid. Specific examples of the inorganic acid include one or more types selected from the group consisting of hydrochloric acid, nitric acid, phosphoric acid, sulfuric acid, boric acid, and hydrofluoric acid. Specific examples of the organic acid include one or more types selected from the group consisting of formic acid, acetic acid, citric acid, methanesulfonic acid, and benzoic acid.

### (Other Components)

The treatment liquid for removal can contain a metal other than the alkali metal and the alkaline earth metal, specifically, one or more types selected from the group consisting of aluminum, iron, chromium, manganese, nickel, zinc, and lead. These metals can be mixed in a manufacturing step, eluted from a container, or mixed in from the environment. These metals can negatively affect the stability of the hypohalite ion, and thus, the contents of the respective metals are preferably 1 ppm or less, more preferably 200 ppt or less, and most preferably 100 ppt or less.

The treatment liquid for removal can contain an additional additive that has been traditionally used in a treatment liquid for a semiconductor, as long as the object of the present invention is not impaired. For example, as the additional additive, one or more types selected from the group consisting of a water-soluble organic solvent, a fluorine compound, a reducing agent, a complexing agent, a chelating agent, a surfactant, an antifoaming agent, a buffer, and a stabilizer can be added. These additives can be added singly, or a plurality of these additives can be added in combination.

The treatment liquid for removal can contain a solvent. Examples of the preferable solvent include the same solvents as those of the oxidation treatment liquid. More specifically, a water from which metal ions, organic impurities, particles, or the like have been removed by a treatment such as distillation, ion exchange, filtration, or various types of adsorption is preferable, and pure water or ultrapure water is particularly preferable. Such water can be obtained by a known method widely used for semiconductor manufacturing.

The treatment liquid for removal is preferably stored at a low temperature and/or under a light-shielded condition. Storage at a low temperature and/or under a light-shielded condition can be expected to provide an effect of inhibiting decomposition of the oxidizer in the treatment liquid. Furthermore, the stability of the treatment liquid can be maintained by storing the treatment liquid in a container filled with an inert gas to prevent contamination of carbon dioxide. In addition, the inner surface of the container, that is, the surface to be in contact with the treatment liquid, is preferably formed of glass or an organic polymer material. This is because the contamination of impurities such as metals, metal oxides, and organic substances can be further reduced when the inner surface of the container is formed of glass or an organic polymer material.

### (Etching Treatment of Semiconductor Substrate)

The removal step can include an etching treatment (hereinafter referred to as the etching treatment) for selectively removing the refractory metal of the semiconductor substrate with respect to copper.

The treatment liquid for removal can be used in the etching treatment of the semiconductor substrate. The etching treatment includes a step of bringing the semiconductor substrate into contact with the treatment liquid for removal.

A wet-etching treatment of a substrate (semiconductor substrate) containing ruthenium and copper will be described as an example of the etching treatment using the treatment liquid for removal. First, a substrate made of a semiconductor (e.g., Si) is prepared. The prepared substrate is subjected to an oxidation treatment of silicon to form a silicon oxide film on the substrate. Thereafter, an interlayer dielectric film made of a low dielectric constant (Low-k) film is formed, and via holes are formed at predetermined intervals. After formation of the via holes, ruthenium is deposited to form a film by thermal chemical vapor deposition (CVD). Thereafter, copper is deposited on the ruthenium film to form a film by electrolytic plating. The copper is then polished by chemical mechanical polishing (CMP). Thereafter, the substrate is immersed in an oxidation treatment liquid to form copper oxide on the surface of the copper (oxidation treatment step). When the excessive ruthenium film is etched by a method such as immersion in the treatment liquid for removal, ruthenium can be selectively etched without corroding or etching copper. A step of washing the oxidation treatment liquid with water or the like can be included immediately after the oxidation treatment step.

The value of the ratio of the etching rate of the refractory metal to the etching rate of copper (etching rate of refractory metal/etching rate of copper) is preferably 50 or more in terms of the semiconductor manufacturing process. The value of this ratio is preferably 80 or more, and more preferably 100 or more.

The temperature for immersion in the oxidation treatment step is not particularly limited, but is, for example, preferably from 10° C. to 90° C., more preferably from 15° C. to 60° C., and most preferably from 20° C. to 50° C.

The immersion time in the oxidation treatment step is not particularly limited, and is, for example, from 0.1 to 60 minutes, preferably from 0.5 to 30 minutes, and more preferably from 1 to 10 minutes.

The temperature at which the refractory metal is etched using the treatment liquid for removal is not particularly limited, and only needs to be determined in consideration of the etching rate of the refractory metal. In a case in which the treatment temperature is high, the stability of the hypohalite ion decreases. On the other hand, the etching rate tends to decrease as the temperature decreases. From such a reason, the temperature for etching the refractory metal is preferably from 10° C. to 90° C., more preferably from 15° C. to 60° C., and most preferably from 20° C. to 50° C.

The time for which the treatment liquid for removal and the semiconductor substrate are brought into contact with each other is in a range of 0.1 to 60 minutes, preferably 0.5 to 30 minutes, and more preferably 1 to 10 minutes, and only needs to be appropriately selected depending on the etching conditions and the washing apparatus to be used. As a rinsing liquid after using each treatment liquid, a rinsing liquid capable of removing an etching residue, particles derived from the metal in the treatment liquid, and organic substances without corroding the metal on the substrate only needs to be appropriately selected. Specific examples thereof include one or more types selected from the group consisting of ultrapure water, isopropyl alcohol, ammonia water, hydrofluoric acid, hydrochloric acid, hydrogen peroxide, an aqueous citric acid solution, acetic acid, sulfuric acid, ozone water, hydrogen water, a mixed liquid of hydrofluoric acid and hydrogen peroxide, a mixed liquid of sulfuric acid and hydrogen peroxide, a mixed liquid of ammonia water and hydrogen peroxide, and a mixed liquid of hydrochloric acid and hydrogen peroxide.

### <Method for Manufacturing Semiconductor Substrate>

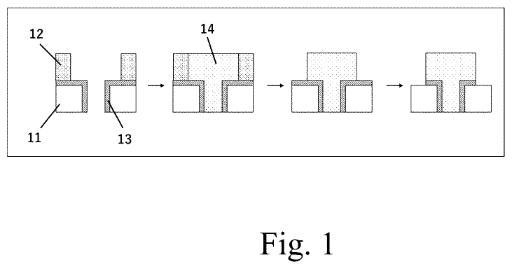

Another embodiment of the present invention is a method for manufacturing a semiconductor substrate, the method including the method for treating a semiconductor substrate according to the embodiment of the present invention described above. The method for manufacturing a semiconductor substrate can include a known step used in the method for manufacturing a semiconductor substrate, such as one or more steps selected from a wafer fabrication step, an oxide film formation step, a transistor formation step, a wiring formation step, and a CMP step. In the manufacturing method of the present embodiment, a semiconductor substrate containing the metal described above as the refractory metal and a metal, for example, copper, whose corrosion potential becomes higher than that of the refractory metal by contact with the treatment liquid for removal can be manufactured. A specific example of the wiring formation step will be described with reference to FIG. 1. First, a substrate 11 having a via hole is prepared, and a layer made of a refractory metal is formed as a seed layer 13 on the substrate. A resist 12 is provided on a predetermined portion of the substrate 11, and then a copper layer 14 is applied by an operation such as electrolytic plating. After the metal is planarized by chemical mechanical polishing, the resist 12 is peeled off. Further, the oxidation treatment step described above is performed to form copper oxide on the surface of the copper. Thereafter, a portion of the seed layer 13 made of the refractory metal is removed by etching with a treatment liquid for removal. According to the method for manufacturing a semiconductor substrate of the present embodiment, the copper oxide formed by the oxidation treatment step protects the surface of the copper during the etching treatment, and thus, the refractory metal (for example, ruthenium) can be selectively removed with respect to copper.

Note that the copper oxide on the surface of the copper can be removed by a known method after the step of removing the refractory metal. For example, the copper oxide is removed by reduction treatment using hydrogen plasma, and the surface of the copper can be exposed again.

### EXAMPLES

Hereinafter, the present invention will be described more specifically with reference to Examples, but the present invention is not limited to these Examples.

### (Quantitative Method of Hypochlorite Ion and Hypobromite Ion Concentrations)

An ultraviolet-visible spectrophotometer (UV-2600, available from Shimadzu Corporation) was used for measurement of hypochlorite ion and hypobromite ion concentrations. A calibration curve was prepared using an aqueous hypobromite ion solution and an aqueous hypochlorite ion solution having known concentrations, and the hypobromite ion and hypochlorite ion concentrations in the treatment liquids were determined. The hypochlorite ion and hypobromite ion concentrations were determined from measurement data when the absorption spectrum was stabilized after the treatment liquid was produced.

### (Quantitative Method of Alkali Metal and Alkaline Earth Metal Concentrations)

The alkali metal and alkaline earth metal concentrations in each treatment liquid were analyzed using a high-frequency inductively-coupled plasma emission spectrometer (iCAP 6500 DuO, available from Thermo Fisher Scientific Inc.). Each treatment liquid was diluted to an appropriate concentration with ultrapure water, and then nitric acid (Ultrapure, available from Kanto Chemical Co., Inc.) was added to adjust the pH to 1 or less. Each treatment liquid after the adjustment was introduced into the apparatus, and a metal concentration was analyzed.

### (Quantitative Method of Halide Ion and Halogen Oxyacid Ion Concentrations)

The halide ion and halogen oxyacid ion concentrations were analyzed using an ion chromatography analyzer (DIONEX INTEGRION HPLC, available from Thermo Fisher Scientific Inc.). KOH was used as an eluent, and an ion analysis column for a hydroxide-based eluent (AS15, available from Thermo Fisher Scientific Inc.) was used as the column. Background noise was removed using a suppressor, after which the halide ion and the halogen oxyacid ion in the treatment liquid were quantified by an electrical conductivity detector.

### (pH Measurement Method)

The pH of each of the treatment liquids prepared in the Examples and Comparative Examples was measured using 10 mL of the treatment liquid and a tabletop PH meter (LAQUA F-73, available from Horiba, Ltd.). Before measuring the treatment liquid, the pH was calibrated using a neutral phosphate pH standard liquid (pH 6.86, available from Kanto Chemical Co., Inc.), a borate pH standard liquid (pH 9.18, available from Kanto Chemical Co., Inc.), and a pH 13.00 standard liquid (available from Hanna Instruments Inc.). The pH measurement was performed after the treatment liquid was prepared and stabilized at 25±1° C.

### (Evaluation)

The produced treatment liquids were used to evaluate an etching rate of ruthenium, an etching rate of copper, and a precipitate on the copper surface by methods described below.

### (Oxidation Treatment Step and Removal Step of Refractory Metal)

An oxide film was formed on a silicon wafer using a batch-type thermal oxidation furnace, and a copper film having a thickness of 200 Å (±10%) was formed thereon using a sputtering method. 40 mL of the treatment liquid for removal was prepared in a fluororesin container with a lid (94.0-mL PFA container, available from As One Corporation). A copper film piece of 10 mm×10 mm, which was cut from a wafer with a copper film having a thickness of 200 Å, was immersed in a chemical liquid (oxidation treatment liquid) containing an oxidizer at 25° C. for 1 minute, and then washed with ultrapure water to obtain a copper film having copper oxide formed on the surface thereof after the oxidation treatment.

The obtained copper film after the oxidation treatment was immersed in an etching treatment liquid (treatment liquid for removal) for the refractory metal at 25° C. for 2 minutes, and then washed with ultrapure water to obtain a copper film after the etching treatment.

### (Etching Rate of Ruthenium)

An oxide film was formed on a silicon wafer using a batch-type thermal oxidation furnace, and a film of ruthenium having a thickness of 1200 Å (+10%) was formed thereon using a sputtering method. The sheet resistance of ruthenium was measured with a four-probe resistance meter (Loresta-GP, available from Mitsubishi Chemical Analytech Co., Ltd.) and converted to a film thickness, and this was taken as the ruthenium film thickness before the etching treatment. 40 mL of the treatment liquid for removal was prepared in a fluororesin container with a lid (94.0-mL PFA container, available from As One Corporation). A ruthenium film piece of 10×10 mm, which was cut from a wafer with a ruthenium film having a thickness of 1200 Å, was immersed in the treatment liquid at a predetermined temperature for 2 minutes to obtain a ruthenium film after the treatment. The film thickness of the ruthenium film after the treatment was measured in accordance with the above-described method, and a difference in film thickness before and after the treatment was divided by the treatment time to obtain the etching rate.

The etching rate of ruthenium was evaluated on the basis of the following evaluation criteria.
A: 100 Å/min or more
B: 50 Å/min or more and less than 100 Å/min
C: 10 Å/min or more and less than 50 Å/min
D: Less than 10 Å/min

### (Stability Evaluation of Etching Rate of Ruthenium)

A ruthenium film piece of 10×10 mm, which was cut from the wafer with a ruthenium film having a thickness of 1200 Å formed by the above method, was immersed in the treatment liquid for removal at 25° C. for 2 minutes, and the thickness of the ruthenium film was measured in accordance with the above-described method and taken as the thickness after the etching treatment. This was defined as the etching rate immediately after the production of the treatment liquid, and the etching rate was evaluated every week thereafter by the above-described method. The number of days during which the obtained etching rate was increased or decreased by ±20% or less relative to the etching rate immediately after the production of the treatment liquid was defined as the stability (days) of the etching rate, and the stability was evaluated on the basis of the following criteria.
A: 180 days or longer
B: 120 days or longer and 179 days or shorter
C: 60 days or longer and 119 days or shorter
D: 59 days or shorter

### (Etching Rate of Copper)

40 mL of the treatment liquid for removal was prepared in a fluororesin container with a lid (94.0-mL PFA container, available from As One Corporation). A copper film piece of 10 mm×10 mm, which was cut from a wafer with a copper film having a thickness of 200 Å, was immersed in an etching treatment liquid for ruthenium at a predetermined temperature for 1 hour. Copper eluted into the liquid was analyzed using a high-frequency inductively-coupled plasma emission spectrometer (iCAP 6500 DuO, available from Thermo Fisher Scientific Inc.). The obtained elution amount of copper was converted into a thickness of the film from the copper density of 8.96 g/cm³. The value obtained by dividing the obtained elution amount in terms of film thickness by the treatment time was taken as the etching rate of copper.

The corrosion of copper was evaluated on the basis of the following evaluation criteria.
A: Less than 1 Å/min
B: 1 Å/min or more and 10 Å/min or less
C: More than 10 Å/min
   (Evaluation of Copper Surface after Etching)

The surface of the copper film obtained in the oxidation treatment step and the removal step of the refractory metal was observed with a field emission scanning electron microscope (JSM-7800F Prime, available from JEOL Ltd.), and the surface was evaluated by the following criteria.
A: No precipitate
B: Precipitate is present in a portion
C: Precipitate is partially present
D: Precipitate is present on the entire surface

### Examples 1 to 3

A solution containing an oxidizer (oxidation treatment liquid) to be used in the oxidation treatment step was prepared as follows to have the composition shown in Table 1. Sodium chlorate (special grade, content 99%, available from Kishida Chemical Co., Ltd.) and ultrapure water were added to a 100-mL fluororesin container to obtain an oxidation treatment liquid.

Next, a treatment liquid (treatment liquid for removal) to be used in the removal step of the refractory metal was prepared as follows to have the composition shown in Table 1. Sodium hypochlorite pentahydrate (Nikkei Ziaso pentahydrate, available from Nippon Light Metal Co., Ltd.), ultrapure water, and 10% aqueous sodium hydroxide solution (Cica special grade, available from Kanto Chemical Co., Inc.) were added to a 100-mL fluororesin container to obtain a treatment liquid for removal.

The treatment by the oxidation treatment step and the removal step of the refractory metal was performed using the obtained treatment liquid, and evaluations described in Table 1 were performed.

### Example 4

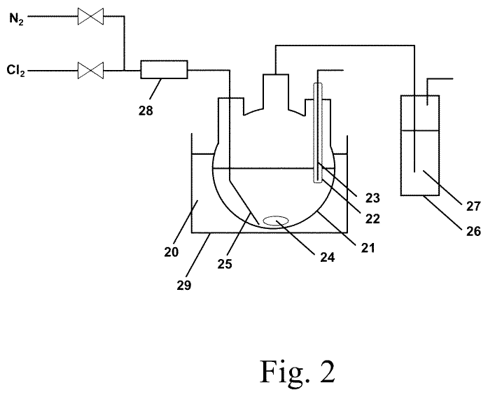

As illustrated in FIG. 2, in a 2-L three-neck flask made of glass 21 (available from Cosmos Bead Co., Ltd.), a 25 mass % aqueous tetramethylammonium hydroxide solution (SD-25, available from Tokuyama Corporation) and ultrapure water were mixed to obtain a 0.63 mol/L aqueous tetramethylammonium hydroxide solution.

A rotator 24 (available from As One Corporation, 30 mm in total length×8 mm in diameter) was then placed in the three-necked flask 21, and a thermometer protection tube 22 (available from Cosmos Bead Co., Ltd., bottom-sealed type) and a thermometer 23 were placed through one opening, and, through another opening, the tip end of a PFA tube 25 (F-8011-02, available from Flon Industry), which was connected to a chlorine gas cylinder and a nitrogen gas cylinder and enabled to be freely switchable between chlorine gas and nitrogen gas, was immersed in the bottom of the solution, and the remaining one opening was connected to a gas-washing bottle 26 (Gas-Washing Bottle, model No. 2450/500, available from As One Corporation) filled with a 5 mass % aqueous sodium hydroxide solution 27.

Thereafter, a magnetic stirrer (C-MAG HS10, available from As One Corporation) was placed at the bottom of the three-necked flask 21, rotation at 300 rpm was performed for stirring, and a chlorine gas (purity 99.999 or more, available from ADEKA CORPORATION) was supplied at a flow rate of 38 mL/min while the outer periphery of the three-necked flask was cooled with ice water 20. The concentration of the obtained aqueous tetramethylammonium hypochlorite solution was 0.31 mol/L, and the pH was 12.0.

Ultrapure water and a 10% aqueous sodium hydroxide solution were added to the obtained aqueous tetramethylammonium hypochlorite solution to obtain the treatment liquid for removal shown in Table 1.

The evaluations shown in Table 1 were performed using the oxidation treatment liquid and the treatment liquid for removal prepared in the same manner as in Example 2.

Note that in FIG. 2, reference numeral 28 denotes a flowmeter, and reference numeral 29 denotes a water bath.

### Example 5

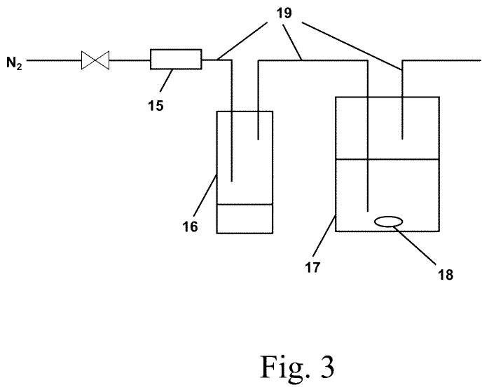

As illustrated in FIG. 3, a 100-mL PFA trap bottle 16 (available from Flonchemical Co., Ltd.) was connected to a nitrogen gas cylinder in such a manner that nitrogen gas could be supplied from one port of the PFA trap bottle 16. The other port was connected to a 500-mL PFA trap bottle 17 (available from Flonchemical Co., Ltd.). 20 mL of bromine (purity>98%, Tokyo Chemical Industry Co., Ltd.) was added to the 100-mL PFA trap bottle 16. At this time, it was confirmed that the tip of a PFA tube 19 was not in contact with liquid bromine. A 10% aqueous sodium hydroxide solution (Cica special grade, available from Kanto Chemical Co., Ltd.) and ultrapure water were added to the 500-mL PFA trap bottle 17 to obtain a 0.34 mol/L aqueous sodium hydroxide solution.

Next, a stirring bar 18 was put into the 500-mL PFA trap bottle 17. A magnetic stirrer (C-MAG HS10, available from As One Corporation) was placed at the bottom of the 500-mL PFA trap bottle 17, and rotation at 300 rpm was performed for stirring. Nitrogen gas was supplied to the 100-mL PFA trap bottle 16 at a flow rate of 100 cc/min, and the gasified bromine was supplied to the 500-mL PFA trap bottle 17 in the subsequent stage for 300 minutes, thereby obtaining an aqueous sodium hypobromite solution having a concentration of 0.12 mol/L and pH of 12.0. A 10% aqueous sodium hydroxide solution and ultrapure water were added to the obtained aqueous sodium hypobromite solution to obtain a treatment liquid for removal shown in Table 1.

The evaluations shown in Table 1 were performed using the oxidation treatment liquid and the treatment liquid for removal prepared in the same manner as in Example 2.

Note that reference numeral 15 in FIG. 3 denotes a flowmeter.

### Example 6

A treatment liquid to be used in the removal step of the refractory metal was obtained in the same manner as in Example 5 except that the liquid into which the bromine gas was blown was changed from the 0.34 mol/L aqueous sodium hydroxide solution to a 0.34 mol/L aqueous tetramethylammonium hydroxide solution to have the composition shown in Table 1.

The evaluations shown in Table 1 were performed using the oxidation treatment liquid and the treatment liquid for removal prepared in the same manner as in Example 2.

### Examples 7 to 9

A treatment liquid was obtained in the same manner as in Example 1 except that sodium bromate (content>99.5%, available from FUJIFILM Wako Pure Chemical Corporation) was used instead of sodium chlorate in the preparation of the oxidation treatment liquid to have the composition shown in Table 1.

The evaluations shown in Table 1 were performed using the obtained treatment liquid.

### Example 10

The evaluations shown in Table 1 were performed using an oxidation treatment liquid prepared by the same method as in Example 8 and a treatment liquid for removal prepared by the same method as in Example 4.

### Example 11

The evaluations shown in Table 1 were performed using an oxidation treatment liquid prepared by the same method as in Example 8 and a treatment liquid for removal prepared by the same method as in Example 5.

### Example 12

The evaluations shown in Table 1 were performed using an oxidation treatment liquid prepared by the same method as in Example 8 and a treatment liquid for removal prepared by the same method as in Example 6.

### Examples 13 to 15

A treatment liquid was obtained in the same manner as in Example 1 except that sodium iodate (content>99.5%, available from FUJIFILM Wako Pure Chemical Corporation) was used instead of sodium chlorate in the preparation of the oxidation treatment liquid to have the composition shown in Table 1.

The evaluations shown in Table 1 were performed using the obtained treatment liquid.

### Example 16

The evaluations shown in Table 1 were performed using an oxidation treatment liquid prepared by the same method as in Example 14 and a treatment liquid for removal prepared by the same method as in Example 4.

### Example 17

The evaluations shown in Table 1 were performed using an oxidation treatment liquid prepared by the same method as in Example 14 and a treatment liquid for removal prepared by the same method as in Example 5.

### Example 18

The evaluations shown in Table 1 were performed using an oxidation treatment liquid prepared by the same method as in Example 14 and a treatment liquid for removal prepared by the same method as in Example 6.

### Examples 19 to 21

Potassium hexacyanidoferrate (III) (purity>99.0%, available from FUJIFILM Wako Pure Chemical Corporation) and ultrapure water were mixed to have the composition shown in Table 1, thereby obtaining an oxidation treatment liquid.

The evaluations shown in Table 1 were performed using the obtained oxidation treatment liquid and a treatment liquid for removal prepared in the same manner as in Example 1.

### Example 22

The evaluations shown in Table 1 were performed using an oxidation treatment liquid prepared by the same method as in Example 20 and a treatment liquid for removal prepared by the same method as in Example 4.

### Example 23

The evaluations shown in Table 1 were performed using an oxidation treatment liquid prepared by the same method as in Example 20 and a treatment liquid for removal prepared by the same method as in Example 5.

### Example 24

The evaluations shown in Table 1 were performed using an oxidation treatment liquid prepared by the same method as in Example 20 and a treatment liquid for removal prepared by the same method as in Example 6.

### Example 25

Ammonium peroxodisulfate (purity>99.0%, available from FUJIFILM Wako Pure Chemical Corporation) and ultrapure water were added to have the composition shown in Table 1, thereby obtaining an oxidation treatment liquid.

The evaluations shown in Table 1 were performed using the obtained treatment liquid and a treatment liquid for removal prepared in the same manner as in Example 1.

### Example 26

The evaluations shown in Table 1 were performed using an oxidation treatment liquid prepared by the same method as in Example 25 and a treatment liquid for removal prepared by the same method as in Example 5.

### Comparative Example 1

The evaluations shown in Table 1 were performed using the treatment liquid for removal used in Example 1 without performing the oxidation treatment step.

### Comparative Example 2

The evaluations shown in Table 1 were performed using the treatment liquid for removal used in Example 5 without performing the oxidation treatment step.

TABLE 1

| | | | Treatment liquid for removal | | | | | | | | |
|---|---|---|---|---|---|---|---|---|---|---|---|
| | Oxidizer of oxidation | | | | Alkali metal or | | | Ruthenium | Stability of | Copper | Observation |
| | treatment liquid | | Oxidizer | | alkaline earth metal | | | etching | ruthenium | etching | result of |
| | Type | mol/L | Type | mol/L | Type | mass % | pH | rate | etching rate | rate | copper surface |
| Example 1 | ClO₃⁻ | 0.001 | ClO⁻ | 0.5 | Na | 1.17 | 12.0 | A | B | A | C |
| Example 2 | ClO₃⁻ | 0.01 | ClO⁻ | 0.5 | Na | 1.17 | 12.0 | A | B | A | B |
| Example 3 | ClO₃⁻ | 0.1 | ClO⁻ | 0.5 | Na | 1.17 | 12.0 | A | B | A | B |
| Example 4 | ClO₃⁻ | 0.01 | ClO⁻ | 0.5 | Na | — | 12.0 | C | B | A | B |
| Example 5 | ClO₃⁻ | 0.01 | BrO⁻ | 0.01 | Na | 0.046 | 12.0 | A | A | A | B |
| Example 6 | ClO₃⁻ | 0.01 | BrO⁻ | 0.01 | Na | — | 12.0 | B | A | A | B |
| Example 7 | BrO₃⁻ | 0.001 | ClO⁻ | 0.5 | Na | 1.17 | 12.0 | A | B | A | C |
| Example 8 | BrO₃⁻ | 0.01 | ClO⁻ | 0.5 | Na | 1.17 | 12.0 | A | B | A | B |
| Example 9 | BrO₃₋ | 0.1 | ClO⁻ | 0.5 | Na | 1.17 | 12.0 | A | B | A | C |
| Example 10 | BrO₃₋ | 0.01 | ClO⁻ | 0.5 | Na | — | 12.0 | C | B | A | B |
| Example 11 | BrO₃₋ | 0.01 | BrO⁻ | 0.01 | Na | 0.046 | 12.0 | A | A | A | B |
| Example 12 | BrO₃₋ | 0.01 | BrO⁻ | 0.01 | Na | — | 12.0 | B | A | A | B |
| Example 13 | lO₃⁻ | 0.001 | ClO⁻ | 0.5 | Na | 1.17 | 12.0 | A | B | A | B |
| Example 14 | lO₃⁻ | 0.01 | ClO⁻ | 0.5 | Na | 1.17 | 12.0 | A | B | A | B |
| Example 15 | lO₃⁻ | 0.1 | ClO⁻ | 0.5 | Na | 1.17 | 12.0 | A | B | A | C |
| Example 16 | lO₃⁻ | 0.01 | ClO⁻ | 0.5 | Na | — | 12.0 | C | B | A | B |
| Example 17 | lO₃⁻ | 0.01 | BrO⁻ | 0.01 | Na | 0.046 | 12.0 | A | A | A | B |
| Example 18 | lO₃⁻ | 0.01 | BrO⁻ | 0.01 | Na | — | 12.0 | B | A | A | B |
| Example 19 | [Fe(CN)₆]³⁻ | 0.001 | ClO⁻ | 0.5 | Na | 1.17 | 12.0 | A | B | A | B |
| Example 20 | [Fe(CN)₆]³⁻ | 0.01 | ClO⁻ | 0.5 | Na | 1.17 | 12.0 | A | B | A | A |
| Example 21 | [Fe(CN)₆]³⁻ | 0.1 | ClO⁻ | 0.5 | Na | 1.17 | 12.0 | A | B | A | A |
| Example 22 | [Fe(CN)₆]³⁻ | 0.01 | ClO⁻ | 0.5 | Na | — | 12.0 | C | B | A | A |
| Example 23 | [Fe(CN)₆]³⁻ | 0.01 | BrO⁻ | 0.01 | Na | 0.046 | 12.0 | A | A | A | A |
| Example 24 | [Fe(CN)₆]³⁻ | 0.01 | BrO⁻ | 0.01 | Na | — | 12.0 | B | A | A | A |
| Example 25 | [S₂O₈]²⁻ | 0.01 | ClO− | 0.5 | Na | 1.17 | 12.0 | A | B | B | A |
| Example 26 | [S₂O₈]²⁻ | 0.01 | BrO⁻ | 0.01 | Na | 0.046 | 12.0 | A | A | B | A |
| Comparative Example 1 | — | — | ClO⁻ | 0.5 | Na | 1.17 | 12.0 | A | B | C | D |
| Comparative Example 2 | — | — | BrO⁻ | 0.01 | Na | 0.046 | 12.0 | A | B | C | D |

As is clear from the results shown in Table 1, by treating a semiconductor substrate by the method according to an embodiment of the present invention, it is possible to selectively remove a refractory metal such as ruthenium contained in the semiconductor substrate with respect to copper, and it is possible to suppress formation of a precipitate on the surface of copper.

### REFERENCE SIGNS LIST

11 Substrate
12 Resist
13 Seed layer
14 Metal layer
15 Flowmeter
16 100-mL PFA trap bottle
17 500-mL PFA trap bottle
18 Rotator
19 PFA tube
20 Ice water
21 Three-necked flask
22 Thermometer protection tube
23 Thermometer
24 Rotator
25 PFA tube
26 Gas-washing bottle
27 5 mass % aqueous sodium hydroxide solution
28 Flowmeter
29 Water bath

This application claims the benefit of Japanese Patent Application No. 2024-138966, filed Aug. 20, 2024, which is hereby incorporated by reference herein in its entirety.

1. A method for treating a semiconductor substrate containing a refractory metal and copper, the method comprising:
an oxidation treatment that includes forming copper oxide on a surface of the copper; and
removing the refractory metal after the oxidation treatment.

2. The method according to claim 1, wherein during the oxidation treatment a solution containing an oxidizer is brought into contact with the semiconductor substrate.

3. The method according to claim 2, wherein the oxidizer is one or more types selected from the group consisting of a hexacyanide metal complex and a halogen oxyacid ion.

4. The method according to claim 1, wherein the removing the refractory metal comprises bringing a treatment liquid containing a hypohalite ion into contact with the semiconductor substrate.

5. The method according to claim 1, wherein the refractory metal is one or more metals selected from the group consisting of titanium, tantalum, ruthenium, molybdenum, tungsten, chromium, iridium, rhodium, platinum, and niobium.

6. A method for manufacturing a semiconductor substrate, the method comprising the method according to claim 1.
